(19) United States
(12) Patent Application Publication
(10) Pub. No.: US 2024/0363515 A1
(43) Pub. Date: Oct. 31, 2024

(54) SEMICONDUCTOR PACKAGE STRUCTURE AND FORMING METHOD THEREOF

(71) Applicant: STATS CHIPPAC SEMICONDUCTOR (JIANGYIN) CO., LTD., JIANGSU (CN)

(72) Inventors: Jeonghan Kim, JIANGSU (CN); Soo Won Lee, JIANGSU (CN); Jian Xu, JIANGSU (CN); Hyoungill Min, JIANGSU (CN); Ruifeng Jiang, JIANGSU (CN)

(73) Assignee: STATS CHIPPAC SEMICONDUCTOR (JIANGYIN) CO., LTD., JIANGSU (CN)

(21) Appl. No.: 18/646,799

(22) Filed: Apr. 26, 2024

(30) Foreign Application Priority Data
Apr. 28, 2023 (CN) 202310486224.7

(51) Int. Cl. H01L 23/498; H01L 21/48; H01L 23/13; H01L 25/16

(52) U.S. Cl. CPC H01L 23/49833; H01L 21/4803; H01L 23/13; H01L 25/16

(57) ABSTRACT

A semiconductor package structure and a forming method therefor are disclosed. The package structure includes: an encapsulant including a first and a second surfaces that are opposite and peripheral side surfaces, wherein the first surface is provided with protruding connection terminals, and junction between the first surface and the peripheral side surfaces are provided with four top corners; a substrate including a flip-chip area, wherein the flip-chip area is provided with four corner areas corresponding to four top corners of the encapsulant; trenches positioned in the substrate in the corner areas or around the corner areas or in the four corner areas and around the four corner areas at the same time; a high-modulus first underfill layer filling four trenches and spaces between the four trenches and the first surface of the encapsulant; and a low-modulus second underfill layer filling a remaining space between the encapsulant and the substrate.

### CROSS-REFERENCE TO RELATED APPLICATION

This application claims the priority benefit of China application serial no. 202310486224.7, filed on Apr. 28, 2023. The entirety of the above-mentioned patent application is hereby incorporated by reference herein and made a part of this specification.

### TECHNICAL FIELD

The present disclosure relates to the field of semiconductor packaging, and in particular, to a semiconductor package structure and a forming method thereof.

### BACKGROUND

Conventionally, System in a package (SiP) technology, such as package in package (PiP) and package on package (PoP), is mostly used to integrate chips. However, with applications such as smart phones and AIoT, not only higher performance is required, but also a small size and low power consumption are required. In this case, it is necessary to stack more chips to reduce the size. Therefore, in addition to the original SiP, current packaging technology is also developing towards three-dimensional packaging technology.

The three-dimensional packaging is well known as 2.5D and 3D packaging. The main concept of the so-called 2.5D packaging is to arrange processors, memory or other chips in parallel on a silicon interposer or an interposer. Specifically, these processors, memory or chips are connected through micro bumps, so that the metal layer in the silicon interposer can connect the electronic signals of different chips; lower solder bumps are connected by through-silicon vias (TSV), and then solders are connected through package carrier boards, so that a tighter interconnection between chips and chips and between chips and substrates is achieved.

However, the existing 2.5D packaging is prone to chips delamination or underfill cracking or chips delamination and underfill cracking.

### SUMMARY

Therefore, the present disclosure provides a forming method for a semiconductor package structure, which includes:
providing an encapsulant, wherein the encapsulant includes a first surface and a second surface that are opposite and peripheral side surfaces that are positioned between the first surface and the second surface, the first surface is provided with protruding connection terminals, and junction between the first surface and the peripheral side surfaces are provided with four top corners;
providing a substrate, wherein the substrate includes a flip-chip area, and the flip-chip area is provided with four corner areas corresponding to four top corners of the encapsulant;
correspondingly forming four trenches in the substrate in the four corner areas or around the four corner areas or in the four corner areas and around the four corner areas at the same time;
flip-chipping the encapsulant on the flip-chip area of the substrate, so that the protruding connection terminal on the first surface of the encapsulant are electrically connected to the substrate;
filling the four trenches and spaces between the four trenches and the first surface of the encapsulant with a high-modulus first underfill layer; and
filling a remaining space between the encapsulant and the substrate with a low-modulus second underfill layer, wherein the low modulus is less than the high modulus.

In some embodiments, the high-modulus first underfill layer has a storage modulus greater than or equal to 10 Gpa, and the low-modulus second underfill layer has a storage modulus less than or equal to 9 Gpa.

In some embodiments, the high-modulus first underfill layer is made of a thermosetting resin.

In some embodiments, the high-modulus first underfill layer is formed by a dispensing process, and the low-modulus second underfill layer is formed by an underfill process.

In some embodiments, the trench is correspondingly positioned in the substrate in the corner area, or the trench is correspondingly positioned in the substrate around the corner area, or the trench is positioned in the substrate both in the corner area and around the corner area.

In some embodiments, the substrate includes a solder mask layer, and the trench is positioned in the solder mask layer.

In some embodiments, the trench is a square trench or an “L”-shaped trench.

In some embodiments, the encapsulant is a 2.5D encapsulant.

In some embodiments, the 2.5D encapsulant includes an interposer and a plurality of semiconductor chips flip-chipped on the interposer, an upper surface and a lower surface of the interposer are provided with a plurality of pads, the interposer is provided with connection layers that are electrically connected to at least part of the pads on the upper surface and the lower surface, the plurality of semiconductor chips are flip-chipped on the upper surface of the interposer, and the protruding connection terminals are connected to the pads on the lower surface of the interposer.

In some embodiments, the encapsulant includes a semiconductor chip and a molding layer for molding the semiconductor chip, and the protruding connection terminals are electrically connected to the semiconductor chip.

The present disclosure further provides a semiconductor package structure, which includes:
an encapsulant wherein the encapsulant includes a first surface and a second surface that are opposite and peripheral side surfaces that are positioned between the first surface and the second surface, the first surface is provided with protruding connection terminals, and junction between the first surface and the peripheral side surfaces are provided with four top corners;
a substrate, wherein the substrate includes a flip-chip area, and the flip-chip area is provided with four corner areas corresponding to four top corners of the encapsulant; corresponding four trenches positioned in the substrate in the four corner areas or around the four corner areas or in the four corner areas and around the four corner areas at the same time;
wherein the encapsulant is flip-chipped on the flip-chip area of the substrate, so that the connection terminals on the first surface of the encapsulant are electrically connected to the substrate;
a high-modulus first underfill layer filling the four trenches and spaces between the four trenches and the first surface of the encapsulant; and
a low-modulus second underfill layer filling a remaining space between the encapsulant and the substrate, wherein the low modulus is less than the high modulus.

In some embodiments, the high-modulus first underfill layer has a storage modulus greater than or equal to 10 Gpa, and the low-modulus second underfill layer has a storage modulus less than or equal to 9 Gpa.

In some embodiments, the high-modulus first underfill layer is made of a thermosetting resin.

In some embodiments, the trench is correspondingly positioned in the substrate in the corner area, or the trench is correspondingly positioned in the substrate around the corner area, or the trench is positioned in the substrate both in the corner area and around the corner area.

In some embodiments, the substrate includes a solder mask layer, and the trench is positioned in the solder mask layer.

In some embodiments, the trench is a square trench or an “L”-shaped trench.

In some embodiments, the encapsulant is a 2.5D encapsulant.

In some embodiments, the 2.5D encapsulant includes an interposer, a plurality of semiconductor chips flip-chipped on the interposer and a molding layer for molding the plurality of chips, an upper surface and a lower surface of the interposer are provided with a plurality of pads, the interposer is provided with connection layers that are electrically connected to at least part of the pads on the upper surface and the lower surface, the plurality of semiconductor chips are flip-chipped on the upper surface of the interposer, and the protruding connection terminals are connected to the pads on the lower surface of the interposer.

In some embodiments, the encapsulant includes a semiconductor chip and a molding layer for molding the semiconductor chip, and the protruding connection terminals are electrically connected to the semiconductor chip.

Compared with the prior art, the technical solutions of the present disclosure have the following advantages.

According to the semiconductor package structure and the forming method therefor of the present disclosure, the package structure includes: an encapsulant, wherein the encapsulant includes a first surface and a second surface that are opposite and peripheral side surfaces that are positioned between the first surface and the second surface, the first surface is provided with protruding connection terminals, and junction between the first surface and the peripheral side surfaces are provided with four top corners; a substrate, wherein the substrate includes a flip-chip area, and the flip-chip area is provided with four corner areas corresponding to four top corners of the encapsulant corresponding four trenches positioned in the substrate in the four corner areas or around the four corner areas or in the four corner areas and around the four corner areas at the same time, wherein the encapsulant is flip-chipped on the flip-chip area of the substrate, so that the connection terminals on the first surface of the encapsulant are electrically connected to the substrate; a high-modulus first underfill layer filling the four trenches and spaces between the four trenches and the first surface of the encapsulant; and a low-modulus second underfill layer filling a remaining space between the encapsulant and the substrate, wherein the low modulus is less than the high modulus. According to the present disclosure, with the organic combination of the trench formed at a specific position and the high-modulus first underfill layer filled between the trench and the encapsulant, the vicinity of the four top corners of the encapsulant can be fixed more tightly and firmly under a high-temperature environment (such as a soldering heat reflow process), and the thermal expansion amount of the high-modulus first underfill layer is reduced, so that the generated stress near the four top corners of the encapsulant is reduced; in addition, the stress of the solder mask layer caused by temperature change can be reduced by forming the trench in the solder mask layer of the substrate, so that the delamination and the filling layer fracture of the formed semiconductor package structure in the vicinity of the four top corners of the encapsulant are prevented.

### BRIEF DESCRIPTION OF DRAWINGS

FIGS. 1 to 14 are structural schematic diagrams of a formation process of a semiconductor package structure according to some embodiments of the present disclosure.

### DETAILED DESCRIPTION OF EMBODIMENTS

The following describes specific embodiments of the present disclosure in detail with reference to accompanying drawings. For ease of description of the embodiments of the present disclosure in detail, schematic diagrams are not partially enlarged according to a general proportion. In addition, the schematic diagrams are merely examples and should not limit the protection scope of the present disclosure. Moreover, the length, width, and depth of a three-dimensional space should be included in actual manufacture.

Some embodiments of the present disclosure first provide a forming method for a semiconductor package structure. The forming method for a semiconductor package structure is described in detail below with reference to the accompanying drawings.

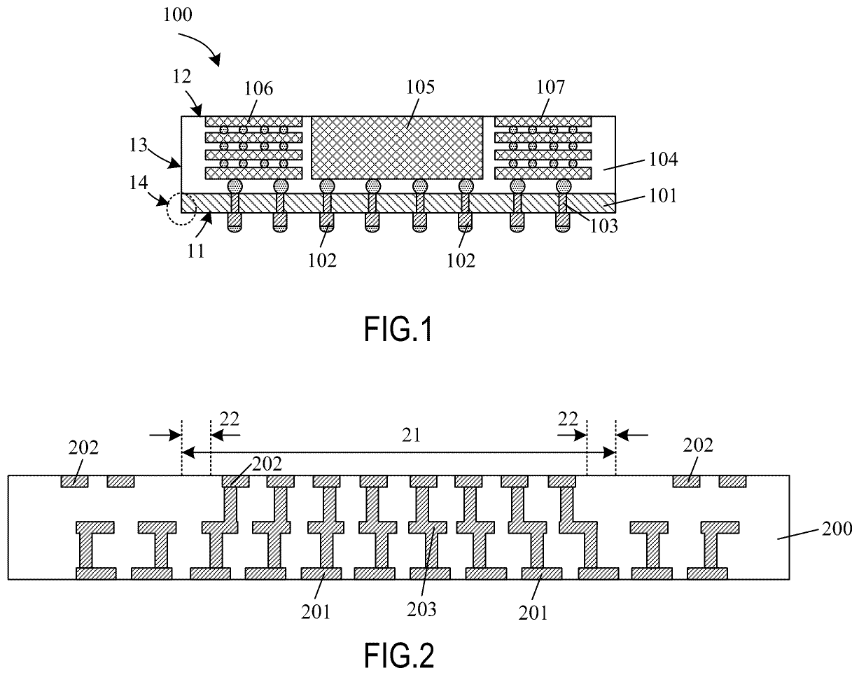

Referring to FIG. 1, an encapsulant 100 is provided, wherein the encapsulant 100 includes a first surface 11 and a second surface 12 that are opposite and peripheral side surfaces 13 that are positioned between the first surface 11 and the second surface 12, the first surface 11 is provided with protruding connection terminals 102, and junction between the first surface 11 and the peripheral side surfaces 13 are provided with four top corners 14.

The encapsulant 100 is then flip-chipped on a substrate to form a semiconductor package structure.

In some embodiments, the encapsulant 100 is in a cube shape, the encapsulant 100 includes a first surface 11 and a second surface 12 that are opposite and four side surfaces 13 positioned between the first surface 11 and the second surface 12, and junctions between the first surface 11 and the four side surfaces 13 are provided with four top corners 14.

In this embodiment, the encapsulant is a 2.5D encapsulant. In an embodiment, the 2.5D encapsulant includes an interposer 101 and a plurality of semiconductor chips (such as 105, 106, 107) flip-chipped on the interposer 101, an upper surface and a lower surface of the interposer 101 are provided with a plurality of pads (not shown in the figure, such as a plurality of upper pads positioned on the upper surface and a plurality of lower pads positioned on the lower surface), the pads may be made of aluminum or copper, the interposer 101 is provided with connection layers 103 that are electrically connected to at least part of the pads on the upper surface and the lower surface, the plurality of semiconductor chips (such as 105, 106, 107) are flip-chipped on the upper surface of the interposer 101, and the protruding connection terminal 102 are connected to the pads on the lower surface of the interposer 101. In some embodiments, the semiconductor chips (such as 105, 106, 107) are electrically connected to pads on the upper surface of the interposer 101 through solder bumps. In some embodiments, the 2.5D encapsulant may further include a molding layer 104 for molding the plurality of semiconductor chips, and the molding layer 104 is made of a resin. In some embodiments, the interposer 101 is a silicon interposer or a redistribution interposer.

A number of the plurality of semiconductor chips are at least two, and the plurality of semiconductor chips may include a logic chip and a memory chip. In some embodiments, the logic chip may include gate arrays, cell substrate arrays, embedded arrays, a structured application specific integrated circuit (ASIC), a field programmable gate array (FPGA), a complex programmable logic device (CPLD), a central processing unit (CPU), a micro processing unit (MPU), a micro controller unit (MCU), a logic integrated circuit (IC), an application processor (AP), a display driver IC (DDI), a radio frequency (RF) chip or a complementary metal-oxide-semiconductor (CMOS) image sensor. In some embodiments, the memory chip may include a volatile memory chip (such as a dynamic random access memory (DRAM) or a static RAM (SRAM)) or a non-volatile memory chip (such as a flash memory (Flash), a phase change RAM (PRAM), a magnetoresistive RAM (MRAM), a ferroelectric RAM (FERAM) or a resistive RAM (RERAM)). In a specific embodiment, the memory chips may comprise a high bandwidth memory (HBM) including a DRAM chip.

In this embodiment, three semiconductor chips are provided, which includes a (first) semiconductor chip 105, a (second) semiconductor chip 106 and a (third) semiconductor chip 107, the (first) semiconductor chip 105 is a logic chip, and the (second) semiconductor chip 106 and the (third) semiconductor chip 107 are high bandwidth memories (HBMs) including a multilayer DRAM chip.

In some other embodiments, the encapsulant may have a different structure, the encapsulant includes a semiconductor chip and a molding layer for molding the semiconductor chip, and the protruding connection terminals are electrically connected to the semiconductor chip.

In some embodiments, the connection terminals 102 include under bump metallization (UBM) layer and solder bumps on the under bump metallization layer. In other embodiments, the connection terminals 102 include under bump metallization layer, metal pillars positioned on the under bump metallization layer, and solder bumps positioned on top of the metal pillars. The under bump metallization layer is made of one or more of aluminum, nickel, tin, tungsten, platinum, copper, titanium, chromium, tantalum, gold and silver; the metal pillars are made of one or more of aluminum, nickel, tin, tungsten, platinum, copper, titanium, chromium, tantalum, gold and silver; and the solder bumps may be made of one or more of tin, tin-silver, tin-lead, tin-silver-copper, tin-silver-zinc, tin-zinc, tin-bismuth-indium, tin-indium, tin-gold, tin-copper, tin-zinc-indium or tin-silver-antimony.

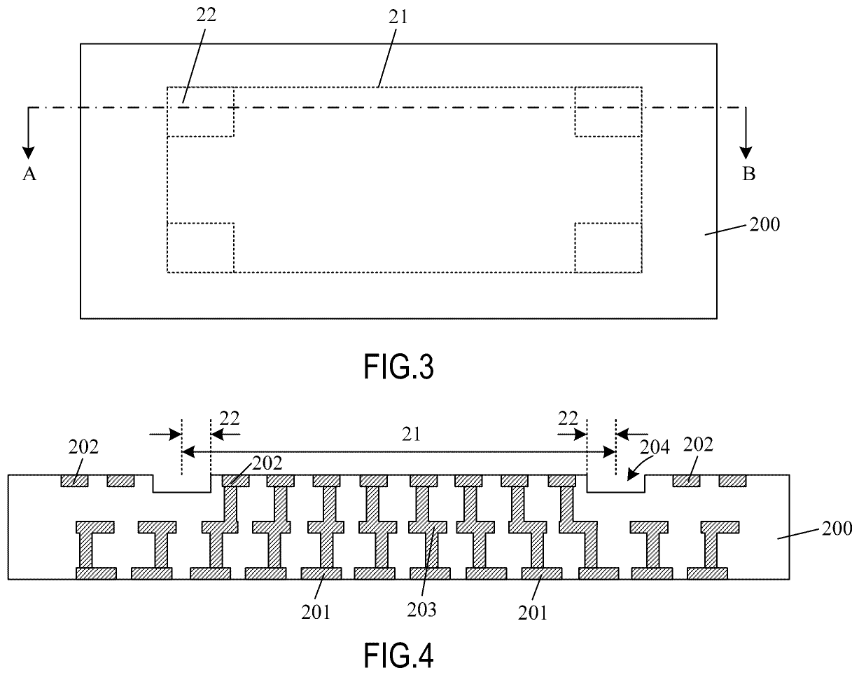

Referring to FIGS. 2 and 3, FIG. 2 is a schematic sectional structural diagram along the AB direction in FIG. 3. A substrate 200 is provided, the substrate 200 includes a flip-chip area 21, and the flip-chip area 21 is provided with four corner areas 22 corresponding to four top corners 14 of the encapsulant 100 (referring to FIG. 1).

The encapsulant 100 is then flip-chipped on the flip-chip area 21 of the substrate 200, a shape of the flip-chip area 21 is the same as that of a projection of the encapsulant 100 on the substrate 200, and the size of the flip-chip area 21 corresponds to or is equal to that of a projection of the encapsulant 100 on the substrate 200.

In some embodiments, the flip-chip area 21 is in a quadrilateral shape, and the four corner areas 22 are respectively positioned at four corners of the quadrilateral shape. In this embodiment, the flip-chip area 21 is in a rectangular or square shape, and the four corner areas 22 are respectively positioned at four corners of the rectangular or square shape.

In some embodiments, an upper surface and a lower surface of the substrate 200 are provided with pads, for example, the upper surface of the substrate 200 is provided with a plurality of (upper) pads 202, and the lower surface of the substrate 200 is provided with a plurality of (lower) pads 201; the substrate 200 is provided with connection layers 203, the connection layers 203 are electrically connected to at least part of the pads on the upper surface and the lower surface of the substrate, and the (upper) pads 202 and the (lower) pads 201 are made of metal, such as copper.

In some embodiments, the surfaces of the (upper) pads 202 and the (lower) pads 201 are provided with a solder layer, and the solder layer is made of tin or a tin alloy.

In some embodiments, the substrate 200 may be one of a resin substrate, a ceramic substrate, a glass substrate, a silicon substrate, a printed circuit board (PCB) or a flexible circuit board (FPC). The substrate 200 may be a single-layer board or a multi-layer board.

In some embodiments, the substrate 200 may include a base and a solder mask layer positioned on the base, and the solder mask layer is a layer of solder mask paint coated on the upper surface of the substrate 200, and may function to prevent solders from overflowing and protect the substrate 200. In some embodiments, the solder mask layer may be made of a photosensitive resin material, the solder mask layer may be formed by a dry film or wet film process, and a pattern such as a trench may be formed in the solder mask layer by exposure and development, followed by curing by heat treatment.

Referring to FIGS. 4 and 5, FIG. 4 is a schematic sectional structural diagram along the AB direction in FIG. 5. Four trenches 204 are correspondingly formed in the substrate 200 in the four corner areas 22 or around the four corner areas 22 or in the four corner areas 22 and around the four corner areas 22.

The purpose of correspondingly forming four trenches 204 in the substrate 200 in the four corner areas 22 or around the four corner areas 22 or in the four corner areas 22 and around the four corner areas 22 in the present disclosure is as follows: the encapsulant 100 is subsequently flip-chipped on the flip-chip area 21 of the substrate 200, after the four trenches 204 and spaces between the four trenches 204 and the first surface of the encapsulant 100 are filled with a high-modulus first underfill layer, the stress near the four top corners of the encapsulant 100 is released while the vicinity of the four top corners of the encapsulant 100 is fixed more tightly and firmly through the organic combination of the trenches 204 at a specific position and the filled high-modulus first underfill layer, so that the formed semiconductor package structure is prevented from delamination and filling layer fracture near the four top corners of the encapsulant 100.

In an embodiment, when the substrate 200 includes a solder mask layer, the trenches 204 are positioned in the solder mask layer, a depth of the trench 204 is less than a thickness of the solder mask layer, and the trench 204 can be formed in the solder mask layer in the corner area 22 or around the corner area 22 or in the corner area 22 and around the corner area 22 by an exposure and development process.

In other embodiments, when the upper surface of the substrate 200 is not provided with a photosensitive material, the trench 204 may be formed in the substrate 200 in the corner area 22 or around the corner area 22 or in the corner area 22 and around the corner area 22 by dry etching, wet etching or laser etching the upper surface of the substrate 200.

In this embodiment, referring to FIGS. 4 and 5, the trench 204 is positioned in the corner area 22 and the substrate 200 around the corner area 22.

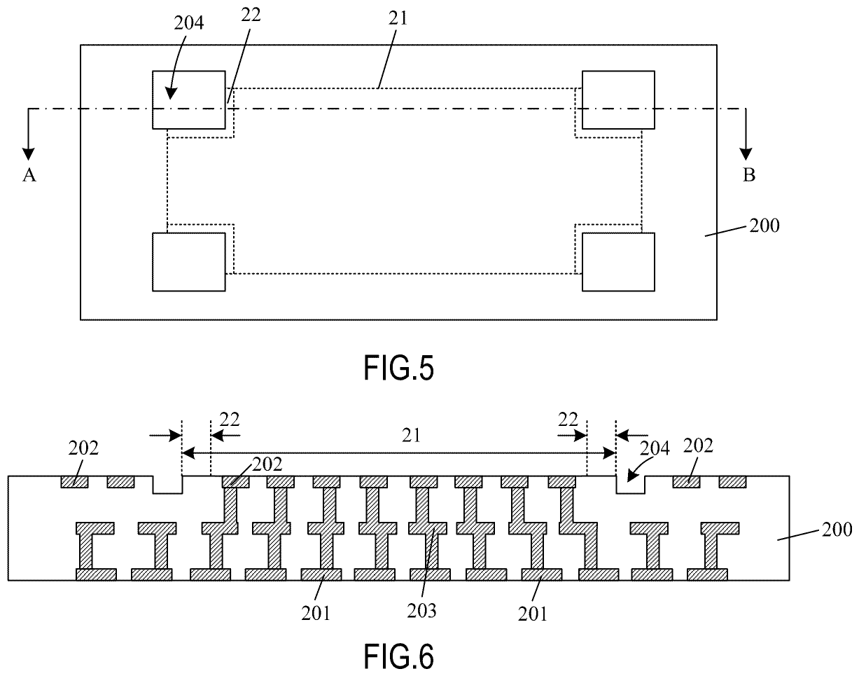

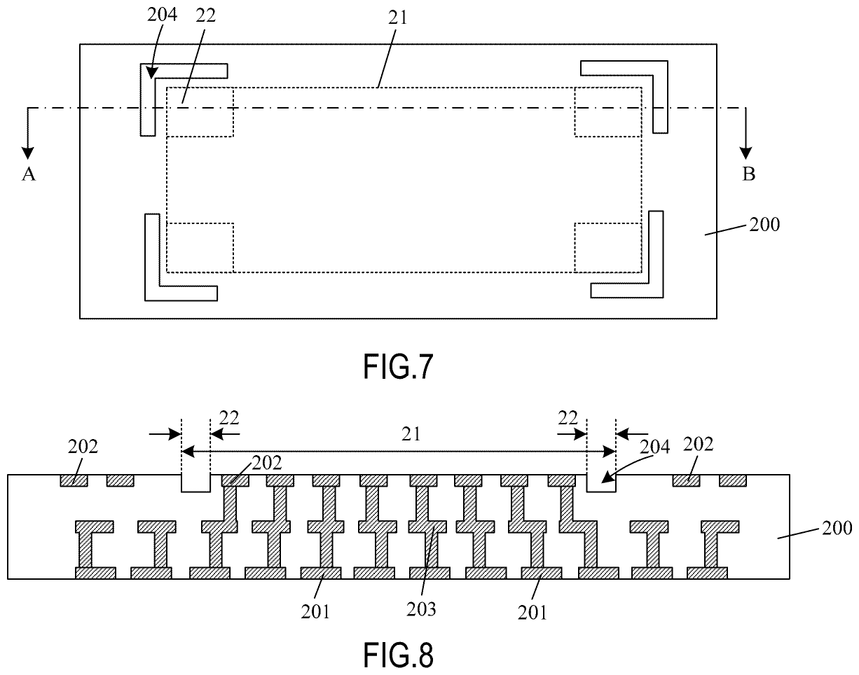

In another embodiment, referring to FIGS. 6 and 7, FIG. 6 is a schematic sectional structural diagram along the AB direction in FIG. 7. The trench 204 is only positioned in the substrate around the corner area.

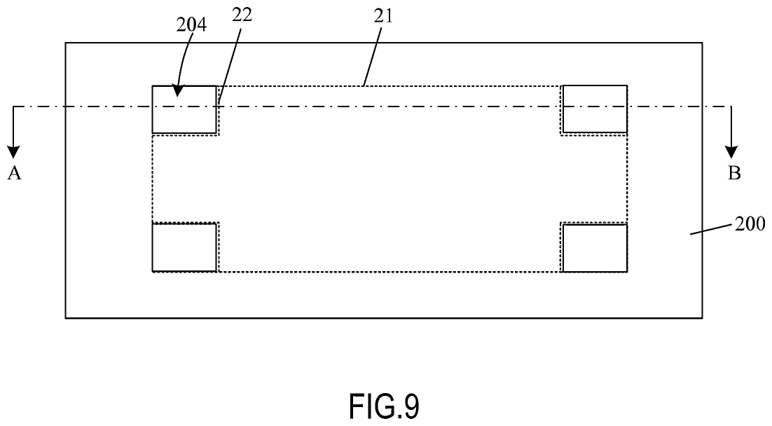

In another embodiment, referring to FIGS. 8 and 9, FIG. 8 is a schematic sectional structural diagram along the AB direction in FIG. 9. The trench 204 is only positioned in the substrate 200 in the corner area 22.

In some embodiments, when the trench 204 is formed in the substrate 200 in the corner area 22 or around the corner area 22 or in the corner area 22 and around the corner area 22, the formed trench 204 may be a square trench (referring to FIGS. 5 and 9) or an “L”-shaped trench (referring to FIG. 7).

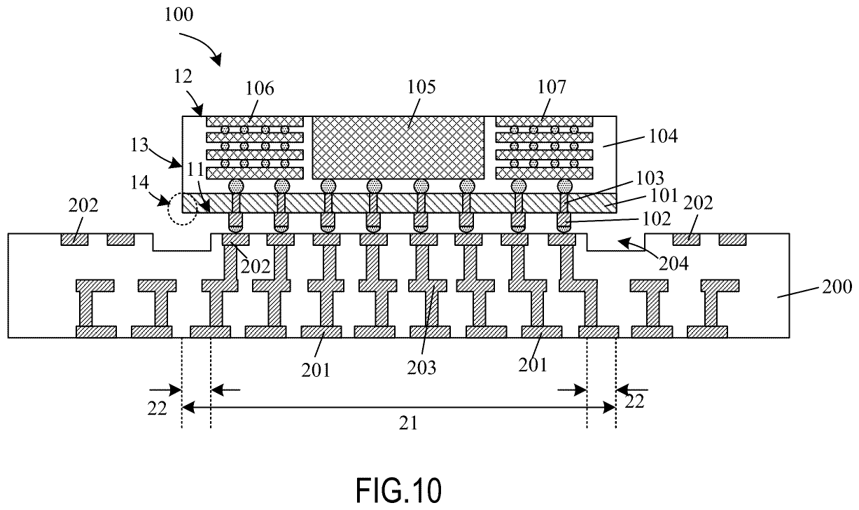

Referring to FIG. 10, the encapsulant 100 is flip-chipped on the flip-chip area 21 of the substrate 200, so that the connection terminals 102 on the first surface of the encapsulant 100 are electrically connected to the substrate 200.

When the encapsulant is flip-chipped on the flip-chip area 21 of the substrate 200 (upper surface), the connection terminals 102 are soldered to the pads on the upper surface of the substrate 200.

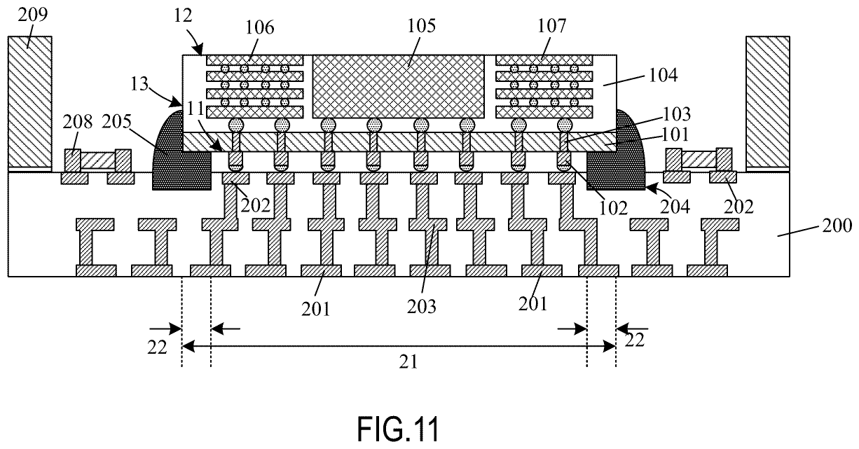

Referring to FIG. 11, the four trenches 204 and spaces between the four trenches 204 and the first surface 11 of the encapsulant are filled with a high-modulus first underfill layer 205.

According to the present disclosure, with the organic combination of the trench 204 formed at a specific position and the high-modulus first underfill layer filled between the trench 204 and the encapsulant 100, the vicinity of the four top corners of the encapsulant 100 can be fixed more tightly and firmly under a high-temperature environment (such as a soldering heat reflow process), and the thermal expansion amount of the high-modulus first underfill layer is reduced, so that the generated stress near the four top corners of the encapsulant 100 is reduced; in addition, the stress of the solder mask layer caused by temperature change can be reduced by forming the trench 204 in the solder mask layer, so that the delamination and the filling layer fracture of the formed semiconductor package structure in the vicinity of the four top corners of the encapsulant 100 are prevented.

The first underfill layer 205 is made of a high-modulus (i.e., high storage modulus) resin material. The high-modulus first underfill layer has a storage modulus greater than or equal to 10 Gpa, which may be 11 Gpa, 12 Gpa, 13 Gpa, 14 Gpa or 15 Gpa. In some embodiments, the high-modulus first underfill layer 205 is made of a thermosetting resin with a storage modulus greater than or equal to 10 Gpa.

In some embodiments, the high-modulus first underfill layer 205 is formed by a dispensing process.

In some embodiments, the high-modulus first underfill layer 205 may fill only the four trenches 204 and the spaces between the four trenches 204 and the first surface 11 of the encapsulant.

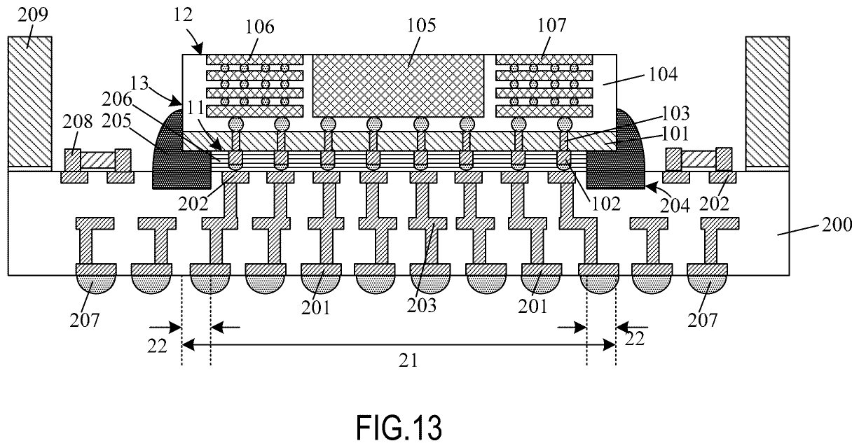

In some embodiments, referring to FIG. 13, in addition to the high-modulus first underfill layer 205 filling the four trenches 204 and the spaces between the four trenches 204 and the first surface 11 of the encapsulant, the high-modulus first underfill layer 205 also covers a portion of the side surfaces 13 of the encapsulant 100 to better secure the encapsulant 100.

In some embodiments, a passive device 208 electrically connected to a portion of (upper) pads may be further formed on the upper surface of the substrate 200, and the passive device 208 may be one or more of a capacitor, an inductor or a resistor.

In some embodiments, a reinforcer 209 surrounding the encapsulant and the passive device 208 may also be attached around the top surface of the substrate 200 to enhance the mechanical property of the substrate 200 and protect the encapsulant and the passive device 208.

In some embodiments, a heat sink (not shown in the figure) may be further attached to the second surface of the encapsulant and the upper surface of the substrate 200, and the heat sink is used to release heat generated from the encapsulant.

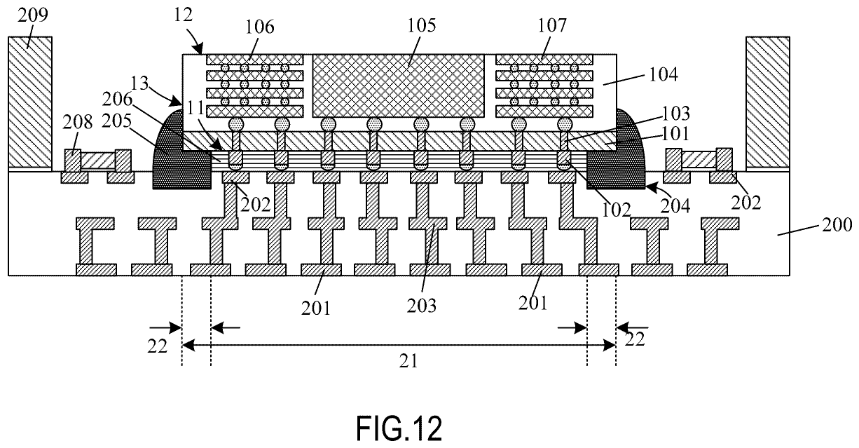

Referring to FIG. 12, a remaining space between the encapsulant and the substrate 200 is filled with a low-modulus second underfill layer 206, wherein the low modulus is less than the high modulus.

The low-modulus second underfill layer 206 is used to protect the solder joints between the encapsulant and the substrate 200 and protect the device from moisture, ionic contaminants and harmful environments such as mechanical stretching, shearing and twisting.

The low-modulus second underfill layer 206 is made of a low-modulus (i.e., low storage modulus) resin material.

The low-modulus second underfill layer 206 has a storage modulus less than or equal to 9 Gpa, which may be 8 Gpa, 7.5 Gpa, 7 Gpa, 6.9 Gpa, 6.5 Gpa or 6 Gpa.

In some embodiments, the low-modulus second underfill layer 206 is made of a thermosetting resin with a storage modulus less than or equal to 9 Gpa. The low-modulus second underfill layer 206 is formed by an underfill process.

Referring to FIG. 13, an external connection terminal 207 is formed on the lower surface of the substrate 200.

The external connection terminal 207 may be the terminal for input/output of a signal or power transmission. For example, the external connection terminal 207 may be the input/output (I/O) terminal that receives an input signal and transmits an output signal, a ground terminal that specifies a ground potential, or a power supply terminal that supplies operating power.

In some embodiments, the external connection terminals 207 include under bump metallization (UBM) layer and solder bumps on the under bump metallization layer. In other embodiments, the connection terminals 102 include under bump metallization layer, metal pillars positioned on the under bump metallization layer, and solder bumps positioned on top of the metal pillars.

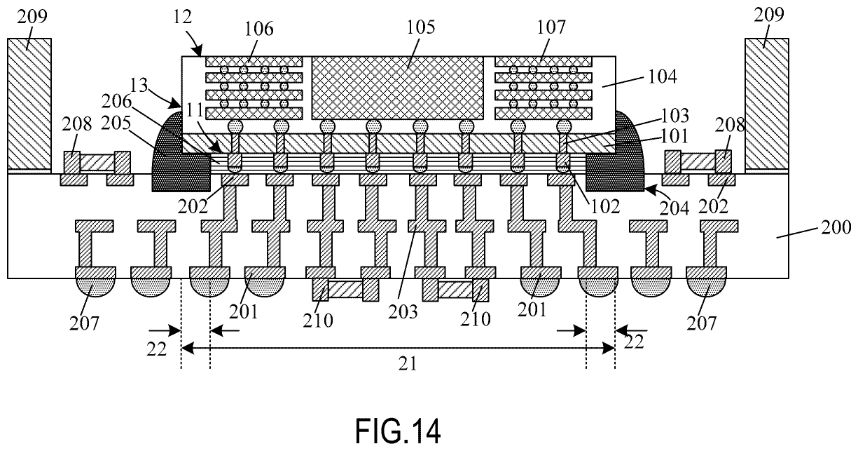

In some embodiments, referring to FIG. 14, a passive device 210 electrically connected to a portion of (lower) pads 201 may be further formed on the lower surface of the substrate 200, and the passive device 210 may be one or more of a capacitor, an inductor or a resistor.

In some embodiments, the present disclosure further provides a semiconductor package structure (it should be noted that, the definition or description of the same or similar parts in this embodiment as in the foregoing embodiments is not repeated herein, and for details, refer to the definition or description of the corresponding parts in the foregoing embodiment), referring to FIG. 13 and referring to FIG. 10, which includes:
an encapsulant, wherein the encapsulant includes a first surface 11 and a second surface 12 that are opposite and peripheral side surfaces 13 that are positioned between the first surface 11 and the second surface 12, the first surface 11 is provided with protruding connection terminals 102, and junction between the first surface 11 and the peripheral side surfaces 13 are provided with four top corners;
a substrate 200, wherein the substrate 200 includes a flip-chip area 21, and the flip-chip area 21 is provided with four corner areas 22 corresponding to four top corners of the encapsulant; corresponding four trenches 204 positioned in the substrate 200 in the four corner areas 22 or around the four corner areas 22 or in the four corner areas 22 and around the four corner areas 22 (referring to FIGS. 4 and 5);
wherein the encapsulant is flip-chipped on the flip-chip area 21 of the substrate 200, so that the connection terminals 102 on the first surface 11 of the encapsulant are electrically connected to the substrate 200;
a high-modulus first underfill layer 205 filling the four trenches 204 and spaces between the four trenches 204 and the first surface of the encapsulant 11; and
a low-modulus second underfill layer 206 filling a remaining space between the encapsulant and the substrate 200, wherein the low modulus is less than the high modulus.

In some embodiments, the high-modulus first underfill layer 205 has a storage modulus greater than or equal to 10 Gpa, and the low-modulus second underfill layer 206 has a storage modulus less than or equal to 9 Gpa.

In some embodiments, the high-modulus first underfill layer 205 is made of a silicon-based resin material, a thermoplastic resin material, a thermally cured resin material or an ultraviolet cured resin material.

In some embodiments, the trench 204 is correspondingly positioned in the substrate in the corner area (referring to FIGS. 8 and 9), or the trench is correspondingly positioned in the substrate around the corner area (referring to FIGS. 6 and 7), or the trench is positioned in the substrate both in the corner area and around the corner area (referring to FIGS. 4 and 5).

In some embodiments, the substrate 200 includes a solder mask layer, and the trench 204 is positioned in the solder mask layer.

In some embodiments, the trench 204 is a square trench or an “L”-shaped trench.

In some embodiments, the encapsulant 100 is a 2.5D encapsulant.

In some embodiments, the 2.5D encapsulant includes an interposer 101 and a plurality of semiconductor chips (105, 106, 107) flip-chipped on the interposer 101, an upper surface and a lower surface of the interposer 101 are provided with a plurality of pads (not shown in the figure), the interposer 101 is provided with connection layers 103 that are electrically connected to at least part of the pads on the upper surface and the lower surface, the plurality of semiconductor chips (105, 106, 107) are flip-chipped on the upper surface of the interposer 101, and the protruding connection terminals 102 are connected to the pads on the lower surface of the interposer 101.

In some embodiments, the encapsulant includes a semiconductor chip and a molding layer for molding the semiconductor chip, and the protruding connection terminals are electrically connected to the semiconductor chip.

The present disclosure has been described with reference to the preferred embodiment, which is not intended to be limited thereto. Those skilled in the art can make possible variations and modifications to the present disclosure using the disclosed methods and technical contents without departing from the spirit and scope of the present disclosure; and therefore, any simple modifications, equivalent changes and modifications made to the above embodiments according to the technical spirit of the present disclosure without departing from the content of the technical solutions of the present disclosure shall fall within the protection scope of the technical solutions of the present disclosure.

1. A forming method for a semiconductor package structure, comprising:
providing an encapsulant, wherein the encapsulant comprises a first surface and a second surface that are opposite and peripheral side surfaces that are positioned between the first surface and the second surface, the first surface is provided with protruding connection terminals, and junction between the first surface and the peripheral side surfaces are provided with four top corners;
providing a substrate, wherein the substrate comprises a flip-chip area, and the flip-chip area is provided with four corner areas corresponding to four top corners of the encapsulant;
correspondingly forming four trenches in the substrate in the four corner areas or around the four corner areas or in the four corner areas and around the four corner areas at the same time;
flip-chipping the encapsulant on the flip-chip area of the substrate, so that the protruding connection terminals on the first surface of the encapsulant are electrically connected to the substrate;
filling the four trenches and spaces between the four trenches and the first surface of the encapsulant with a high-modulus first underfill layer; and
filling a remaining space between the encapsulant and the substrate with a low-modulus second underfill layer, wherein the low modulus is less than the high modulus.

2. The forming method for the semiconductor package structure according to claim 1, wherein the high-modulus first underfill layer has a storage modulus greater than or equal to 10 Gpa, and the low-modulus second underfill layer has a storage modulus less than or equal to 9 Gpa.

3. The forming method for the semiconductor package structure according to claim 1, wherein the high-modulus first underfill layer is made of a thermosetting resin.

4. The forming method for the semiconductor package structure according to claim 1, wherein the high-modulus first underfill layer is formed by a dispensing process, and the low-modulus second underfill layer is formed by an underfill process.

5. The forming method for the semiconductor package structure according to claim 1, wherein the four trenches are correspondingly positioned in the substrate in the four corner areas, or the four trenches are correspondingly positioned in the substrate around the four corner areas, or the four trenches are positioned in the substrate both in the four corner areas and around the four corner areas.

6. The forming method for the semiconductor package structure according to claim 1, wherein the substrate comprises a solder mask layer, and the four trenches are positioned in the solder mask layer.

7. The forming method for the semiconductor package structure according to claim 5, wherein each of the four trenches is a square trench or an “L”-shaped trench.

8. The forming method for the semiconductor package structure according to claim 1, wherein the encapsulant is a 2.5D encapsulant.

9. The forming method for the semiconductor package structure according to claim 8, wherein the 2.5D encapsulant comprises an interposer and a plurality of semiconductor chips flip-chipped on the interposer, an upper surface and a lower surface of the interposer are provided with a plurality of pads, the interposer is provided with connection layers that are electrically connected to at least part of the plurality of pads on the upper surface and the lower surface, the plurality of semiconductor chips are flip-chipped on the upper surface of the interposer, and the protruding connection terminals are connected to the plurality of pads on the lower surface of the interposer.

10. The forming method for the semiconductor package structure according to claim 1, wherein the encapsulant comprises a semiconductor chip and a molding layer for molding the semiconductor chip, and the protruding connection terminals are electrically connected to the semiconductor chip.

11. A semiconductor package structure, comprising:
a encapsulant, wherein the encapsulant comprises a first surface and a second surface that are opposite and peripheral side surfaces that are positioned between the first surface and the second surface, the first surface is provided with protruding connection terminals, and junction between the first surface and the peripheral side surfaces are provided with four top corners;
a substrate, wherein the substrate comprises a flip-chip area, and the flip-chip area is provided with four corner areas corresponding to four top corners of the encapsulant; corresponding four trenches positioned in the substrate in the four corner areas or around the four corner areas or in the four corner areas and around the four corner areas at the same time;
wherein the encapsulant is flip-chipped on the flip-chip area of the substrate, so that the protruding connection terminals on the first surface of the encapsulant are electrically connected to the substrate;
a high-modulus first underfill layer filling the four trenches and spaces between the four trenches and the first surface of the encapsulant; and
a low-modulus second underfill layer filling a remaining space between the encapsulant and the substrate, wherein the low modulus is less than the high modulus.

12. The semiconductor package structure according to claim 11, wherein the high-modulus first underfill layer has a storage modulus greater than or equal to 10 Gpa, and the low-modulus second underfill layer has a storage modulus less than or equal to 9 Gpa.

13. The semiconductor package structure according to claim 11, wherein the high-modulus first underfill layer is made of a thermosetting resin.

14. The semiconductor package structure according to claim 11, wherein the four trenches are correspondingly positioned in the substrate in the four corner areas, or the four trenches are correspondingly positioned in the substrate around the four corner areas, or the four trenches are positioned in the substrate both in the four corner areas and around the four corner areas.

15. The semiconductor package structure according to claim 11, wherein the substrate comprises a solder mask layer, and the four trenches are positioned in the solder mask layer.

16. The semiconductor package structure according to claim 14, wherein each of the four trenches are a square trench or an “L”-shaped trench.

17. The semiconductor package structure according to claim 14, wherein the encapsulant is a 2.5D encapsulant.

18. The semiconductor package structure according to claim 17, wherein the 2.5D encapsulant comprises an interposer, a plurality of semiconductor chips flip-chipped on the interposer and a molding layer for molding the plurality of chips, an upper surface and a lower surface of the interposer are provided with a plurality of pads, the interposer is provided with connection layers that are electrically connected to at least part of the plurality of pads on the upper surface and the lower surface, the plurality of semiconductor chips are flip-chipped on the upper surface of the interposer, and the protruding connection terminals are connected to the plurality of pads on the lower surface of the interposer.

19. The semiconductor package structure according to claim 11, wherein the encapsulant comprises a semiconductor chip and a molding layer for molding the semiconductor chip, and the protruding connection terminal is electrically connected to the semiconductor chip.
